(19) United States
(12) Patent Application Publication
(10) Pub. No.: US 2026/0197009 A1
(43) Pub. Date: Jul. 9, 2026

(54) DELAY CIRCUIT, ANALOG TO DIGITAL CONVERTER, AND DELAY AMOUNT CONTROLLING METHOD

(71) Applicant: United Microelectronics Corp., Hsinchu (TW)

(72) Inventor: Hsuan Chih Yeh, New Taipei City (TW)

(73) Assignee: United Microelectronics Corp., Hsinchu (TW)

(21) Appl. No.: 19/050,128

(22) Filed: Feb. 11, 2025

(30) Foreign Application Priority Data
Jan. 3, 2025 (TW) 114100208

(51) Int. Cl. H03M 1/10; H03K 5/133; H03M 1/12

(52) U.S. Cl. CPC H03M 1/1014; H03K 5/133; H03M 1/1245

(57) ABSTRACT

A delay circuit includes a delay chain and a calibration circuit. The delay chain includes a plurality of delay cells coupled in series. The delay chain provides a delay amount, and delays a clock signal by the delay amount to generate a delayed clock signal. The calibration circuit is coupled to the delay chain, counts the number of pulses of the delayed clock signal during a preset time period to generate a count value, and generates calibration information according to the count value. The delay chain adjusts the delay amount by adjusting a transmission delay of at least one of the delay cells according to the calibration information.

### CROSS-REFERENCE TO RELATED APPLICATION

This application claims the priority benefit of Taiwan application serial no. 114100208, filed on Jan. 3, 2025. The entirety of the above-mentioned patent application is hereby incorporated by reference herein and made a part of this specification.

### BACKGROUND

### Technical Field

The disclosure relates to a delay circuit, an analog to digital converter, and a delay amount controlling method, and particularly relates to a delay circuit, an analog to digital converter, and a delay amount controlling method for solving the problem of extended working time caused by metastable events.

### Related Art

In the related art, an analog to digital converter (ADC) performs signal conversion operations by comparing a sampling voltage with a reference voltage, and the ADC generates corresponding digital codes based on the comparison results of the sampling comparison operation at the transition edges of a clock signal. If the comparison operation at the clock transition edge is unstable, then metastable events may occur.

To overcome the metastable events, ADCs in the related art provide metastable sensors to delay the clock signal by a delay amount. However, due to manufacturing parameter variations and temperature changes, the delay amount is difficult to control.

### SUMMARY

The disclosure provides a delay circuit, an analog to digital converter, and a delay amount controlling method that can adjust a delay amount of delaying a clock signal.

The delay circuit of the disclosure includes a delay chain and a calibration circuit. The delay chain includes multiple delay cells coupled in series. The delay chain provides a delay amount, and delays a clock signal by the delay amount to generate a delayed clock signal. The calibration circuit is coupled to the delay chain, counts the number of pulses of the delayed clock signal during a preset time period to generate a count value, and generates calibration information according to the count value. The delay chain adjusts the delay amount by adjusting a transmission delay of at least one of the delay cells according to the calibration information.

The analog to digital converter of the disclosure includes a comparison circuit and a controller. The comparison circuit compares a sampling voltage with a reference voltage based on a clock signal to generate a comparison ready signal. The controller includes a delay circuit and a logic circuit. The logic circuit determines whether a metastable event occurs according to the comparison ready signal. The delay circuit provides a delayed clock signal. The delay circuit includes a delay chain and a calibration circuit. The delay chain includes multiple delay cells coupled in series. The delay chain provides a delay amount, and delays the clock signal by the delay amount to generate the delayed clock signal. The calibration circuit is coupled to the delay chain, counts the number of pulses of the delayed clock signal during a preset time period to generate a count value, and generates calibration information according to the count value. The delay chain adjusts the delay amount by adjusting a transmission delay of at least one of the delay cells according to the calibration information.

The delay amount controlling method of the disclosure includes the following. A delay amount is provided by a delay chain, in which the delay chain has multiple delay cells coupled in series. A delayed clock signal is generated by delaying a clock signal according to the delay amount. The number of pulses of the delayed clock signal is counted during a preset time period to generate a count value. Calibration information is generated according to the count value. The delay amount is adjusted by adjusting a transmission delay of at least one of the delay cells according to the calibration information.

Based on the above, the delay circuit, the analog to digital converter, and the delay amount controlling method of the disclosure provide the delay circuit with the delay amount calibration functionality. As such, in addition to solving the problem of highly variable delay amounts in existing analog to digital converters, the disclosure can also ensure that the delay amount is within an appropriate range to avoid excessively short or long delay amounts causing prolonged comparison times.

### BRIEF DESCRIPTION OF THE DRAWINGS

FIG. 1 shows a schematic diagram of a delay circuit according to an embodiment of the disclosure.

FIG. 2A shows a schematic diagram of a delay chain according to an embodiment of the disclosure.

FIG. 2B shows a waveform diagram of a clock signal of the delay chain in FIG. 2A.

FIG. 3 shows a schematic diagram of an implementation of the delay chain according to an embodiment of the disclosure.

FIG. 4 shows a schematic diagram of another implementation of the delay chain according to an embodiment of the disclosure.

FIG. 5 shows a schematic diagram of a calibration circuit according to an embodiment of the disclosure.

FIG. 6 shows a schematic diagram of a delay circuit according to an embodiment of the disclosure.

FIG. 7 shows a schematic diagram of an analog to digital converter according to an embodiment of the disclosure.

FIG. 8 shows a schematic diagram of an analog to digital converter according to an embodiment of the disclosure.

FIG. 9 shows a flowchart of a delay amount controlling method according to an embodiment of the disclosure.

FIG. 10 shows a flowchart of a delay amount controlling method according to an embodiment of the disclosure.

### DESCRIPTION OF THE EMBODIMENTS

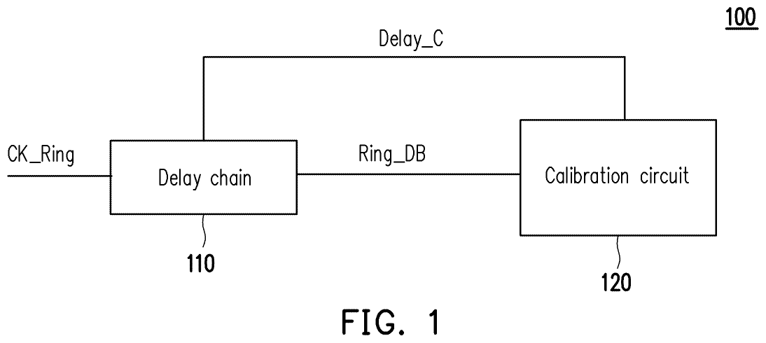

Please refer to FIG. 1, which shows a schematic diagram of a delay circuit 100 according to an embodiment of the disclosure. The delay circuit 100 includes a delay chain 110 and a calibration circuit 120. As shown in FIG. 1, the calibration circuit 120 is coupled to the delay chain 110. The delay chain 110 is used to provide a delay amount. The delay chain 110 receives a clock signal CLK_in, and generates a delayed clock signal Ring_DB by delaying the clock signal CLK_in by a delay amount. In this embodiment, the delay chain 110 includes multiple delay cells coupled in series.

Furthermore, the calibration circuit 120 receives the delayed clock signal Ring_DB, and generates calibration information Delay_C according to the delayed clock signal Ring_DB. In detail, the calibration circuit 120 counts the number of pulses of the delayed clock signal Ring_DB during a preset time period to generate a count value, and generates the calibration information Delay_C according to the count value.

On the other hand, the calibration circuit 120 may provide the calibration information Delay_C to the delay chain 110. In the embodiment, the delay chain 110 may adjust the provided delay amount by adjusting a transmission delay of at least one of the delay cells according to the received calibration information Delay_C.

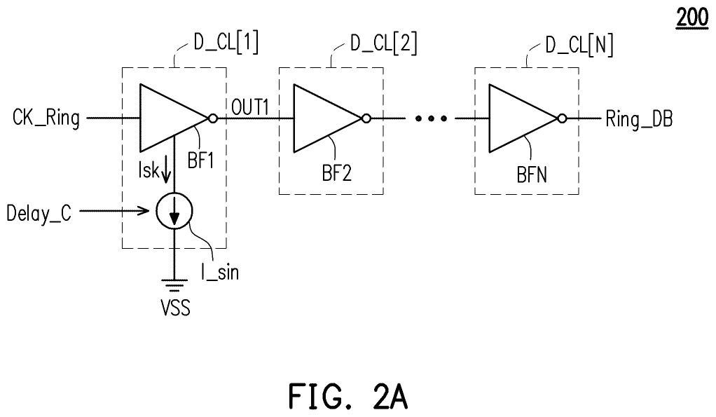

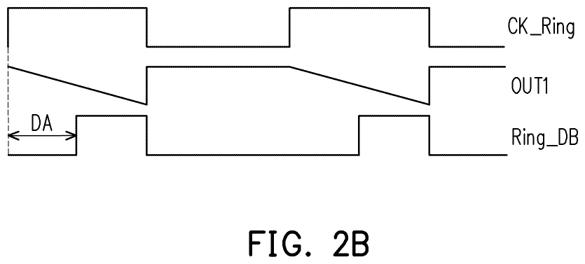

Please refer to FIG. 2A, which shows a schematic diagram of a delay chain 200 according to an embodiment of the disclosure. In this embodiment, the delay chain 110 in FIG. 1 may be implemented by the delay chain 200. As shown in FIG. 2A, the delay chain 200 includes multiple delay cells D_CL[1] to D_CL[N]. The delay cells D_CL[1] to D_CL[N] are coupled in series sequentially. In this embodiment, the delay cells D_CL[1] to D_CL[N] may respectively include multiple signal buffers BF1 to BFN. In detail, the signal buffers BF1, BF2 may be inverters, and the signal buffer BF3 may be a non-inverting buffer. On the other hand, the delay cell D_CL[1] serves as a selected delay cell to adjust the transmission delay according to the calibration information Delay_C.

Specifically, the selected delay cell D_CL[1] may further include a current source I_sin. The current source I_sin is coupled in the path where the corresponding signal buffer (that is, the delay cell D_CL[1]) receives a reference ground voltage VSS. The current source I_sin receives the calibration information Delay_C, and provides a sink current Isk according to the calibration information Delay_C. By controlling the current value of the sink current Isk, the delay cell D_CL[1] may control the falling time of the falling edge of a generated clock signal OUT1. In the embodiment, the larger the sink current Isk provided by the current source I_sin, the shorter the falling time of the clock signal OUT1 generated by the delay cell D_CL[1]; conversely, the smaller the sink current Isk provided by the current source I_sin, the longer the falling time of the clock signal OUT1 generated by the delay cell D_CL[1]. In this way, the control operation of the delay amount provided by the delay chain 200 can be achieved.

Incidentally, due to the function of the buffer BF1 as an inverting circuit, the clock signal OUT1 generated by the delay cell D_CL[1] may substantially have an opposite phase to the clock signal CK_Ring.

Through the sequential operation of the delay cells D_CL[1] to DCL[N], the delay chain 200 may generate the delayed clock signal Ring_DB at the output terminal of the buffer of delay cell D_CL[N] according to the clock signal CK_Ring.

Please refer to FIG. 2B, which shows a waveform diagram of the clock signal in the delay chain 200 in FIG. 2A. As shown in FIG. 2B, taking the clock signal CK_Ring as a square wave signal as an example, the delay cell D_CL[1] at the first end of the delay chain 200 receives the clock signal CK_Ring, and generates the clock signal OUT1 with a pulled-down ramp signal corresponding to the positive voltage period of the clock signal CK_Ring; and generates the clock signal OUT1 with a relatively high voltage corresponding to the zero voltage period of the clock signal CK_Ring. The delay cell D_CL[2] may receive the clock signal OUT1, and generate an output signal by inverting the clock signal OUT1. At the output terminal of the delay cell D_CL[N] at the second end of the delay chain 200, the delayed clock signal Ring_DB, which is also a square wave signal, may be generated according to the output signal generated by the delay cell D_CL[2]. Here, based on the reshaping operations performed on the clock signal OUT1 by the delay cell D_CL[2] and the delay cell D_CL[N], there may be a delay amount DA between the rising edge of the delayed clock signal Ring_DB and the corresponding rising edge of the input clock signal CK_Ring.

Incidentally, the slope of the ramp signal in the clock signal OUT1 may be associated with the magnitude of the sink current Isk provided by the current source I_sin. In the embodiment, the sink current Isk provided by the current source I_sin is positively correlated with the absolute value of the slope of the ramp signal in the clock signal OUT1.

It should be noted here that in this embodiment of the disclosure, there is no specific limitation on the number of the delay cells D_CL[1] to D_CL[N] in the delay chain 200. The designer may set and adjust the number of the delay cells D_CL[1] to D_CL[N] in the delay chain 200 according to actual application requirements. The drawing in FIG. 2 is merely for illustrative purposes and should not be used to restrict the scope of implementation of this disclosure.

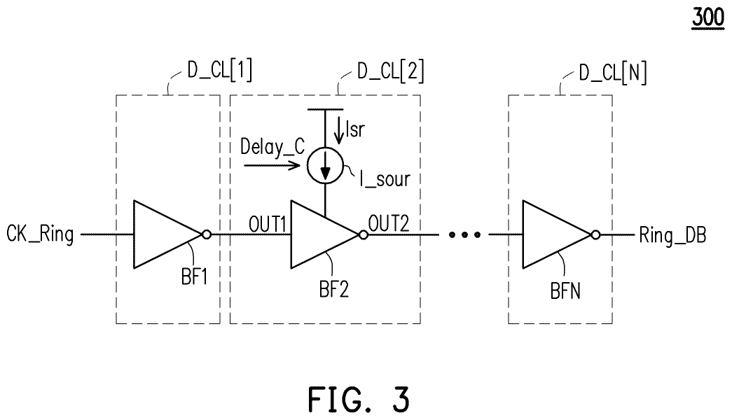

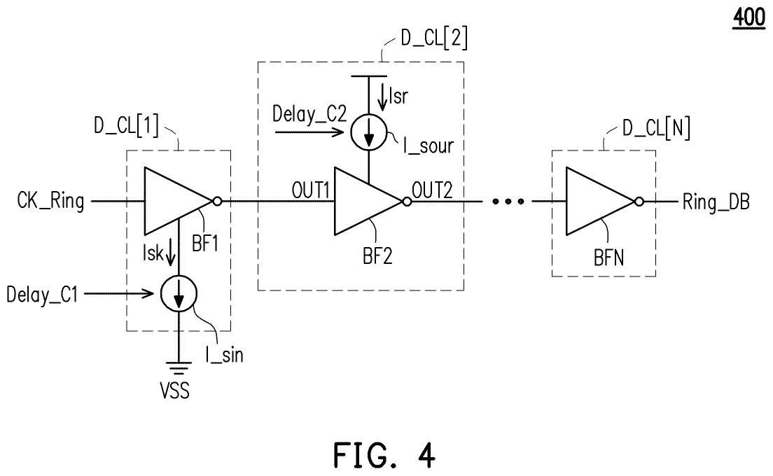

Please refer to FIG. 3 and FIG. 4, which show schematic diagrams of several different implementations of the delay chain 110 in the embodiment of the disclosure. In FIG. 3, in a delay chain 300, the delay cell D_CL[2] may serve as the selected delay cell. The delay cell D_CL[2] includes the buffer BF2 and a current source I_sour. The current source I_sour is coupled in the path where the corresponding signal buffer (that is, the delay cell D_CL[2]) receives a power supply voltage VDD, and provides a source current Isr according to the calibration information Delay_C. In this embodiment, by controlling the current value of the source current Isr, the delay cell D_CL[2] may control the rising time of the rising and falling edges of a generated clock signal OUT2. In the embodiment, the larger the source current Isr provided by the current source I_sour, the shorter the falling time of the clock signal OUT2 generated by the delay cell D_CL[2]; conversely, the smaller the source current Isr provided by the current source I_sour, the longer the rising time of the clock signal OUT2 generated by the delay cell D_CL[2]. In this way, the control operation of the delay amount provided by the delay chain 300 can be achieved.

In FIG. 4, a delay chain 400 may be an implementation combining the delay chains 200 and 300 in FIG. 2A and FIG. 3. Here, the delay cells D_CL[1] and D_CL[2] may simultaneously serve as the selected delay cells. The delay cell D_CL[1] has the pull-down current source I_sin while the delay cell D_CL[2] has the pull-up current source I_sour. In this embodiment, the calibration information Delay_C provided by the calibration circuit 120 in FIG. 1 includes calibration information Delay_C1 and calibration information Delay_C2, and the current source I_sin and the current source I_sour are controlled by the calibration information Delay_C1 and Delay_C2 respectively, in which the calibration information Delay_C1 and Delay_C2 may be the same or different from each other.

From the embodiments, it may be known that the delay chains 110, 200, 300, and 400 may set at least one of the delay cells D_CL[1] to D_CL[N] as the selected delay cell, and adjust the delay amount by adjusting the transmission delay of the selected delay cell.

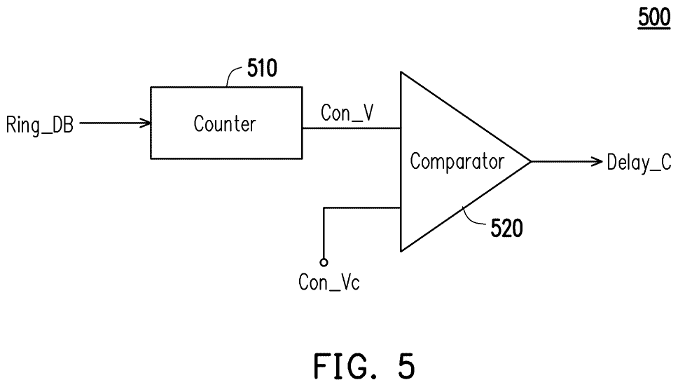

Please refer to FIG. 1 and FIG. 5 together. FIG. 5 shows a schematic diagram of a calibration circuit 500 according to an embodiment of the disclosure. In this embodiment, the calibration circuit 120 in FIG. 1 may be implemented by the calibration circuit 500. As shown in FIG. 5, the calibration circuit 500 includes a counter 510 and a comparator 520. An input terminal of the comparator 520 is coupled to the counter 510. The counter 510 counts the number of pulses of the delayed clock signal Ring_DB during the preset time period to generate a count value Con_V, and transmits the count value Con_V to the comparator 520. Another input terminal of the comparator 520 receives a threshold Con_Vc, and compares the count value Con_V with the threshold Con_Vc to generate the calibration information Delay_C. When the count value Con_V is less than the threshold Con_Vc, the comparator 520 increases the calibration information Delay_C by an offset value. Moreover, when the calibration information Delay_C increases, the delay amount of the delay chain 110 may correspondingly decrease. In this embodiment, through the calibration information Delay_C, the delay amount provided by the delay chain 110 can be effectively controlled, ensuring that the system can operate normally.

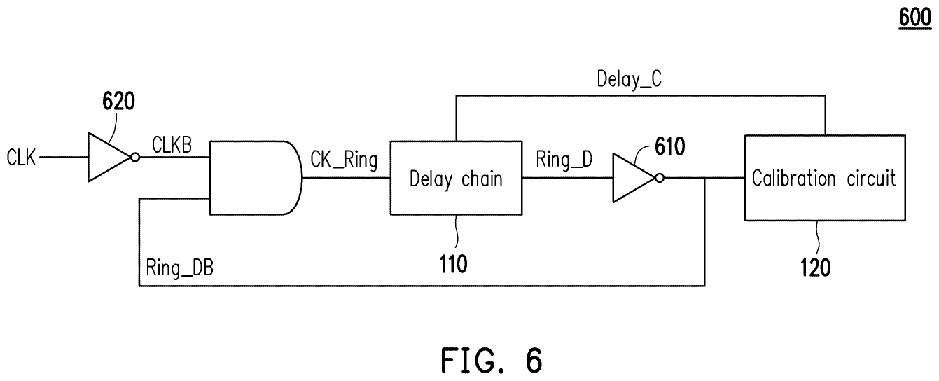

Please refer to FIG. 1 and FIG. 6 together. FIG. 6 shows a schematic diagram of a delay circuit 600 according to an embodiment of the disclosure. Compared to the delay circuit 100, the delay circuit 600 further includes an inverter 610, an inverter 620, and an AND gate 630. The inverter 610 is coupled between the delay chain 110 and the calibration circuit 120. The output terminals of the inverter 610 and the inverter 620 are coupled to two different input terminals of the AND gate 630 respectively. The output terminal of the AND gate 630 is coupled to the delay chain 110. In this configuration, the inverter 610 inverts the delayed clock signal Ring_D generated by the delay chain 110, and transmits the delayed clock signal Ring_DB to an input terminal of the AND gate 630. The inverter 620 receives the clock signal CLK, inverts the clock signal CLK into a clock signal CLKB, and further transmits the clock signal CLKB to another input terminal of the AND gate 630. Then, the AND gate 630 generates the clock signal CK_Ring according to the clock signal CLKB and the delayed clock signal Ring_DB. The delay chain 110 then generates the adjusted delayed clock signal Ring_D according to the clock signal CK_Ring and the calibration information Delay_C.

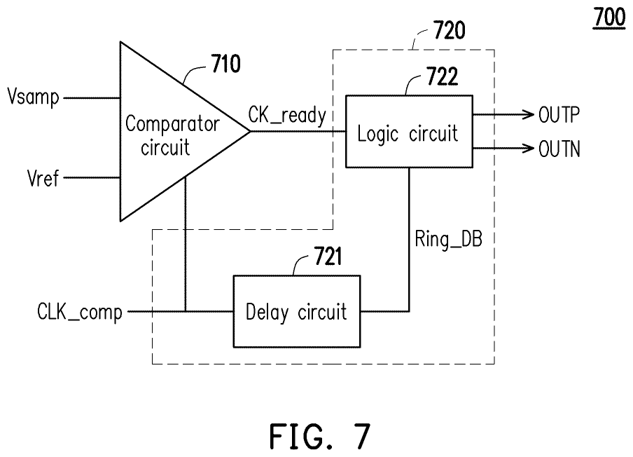

Please refer to FIG. 7, which shows a schematic diagram of an analog to digital converter 700 according to an embodiment of the disclosure. The analog to digital converter 700 includes a comparison circuit 710 and a controller 720. The controller 720 includes a delay circuit 721 and a logic circuit 722. In this embodiment, the delay circuit 721 may be implemented by the delay circuit 100 or 600. The comparison circuit 710, based on a clock signal CLK_comp, compares the sampling voltage Vsamp with the reference voltage Vref to generate a comparison ready signal CK_ready. The logic circuit 722 determines whether a metastable event occurs according to the comparison ready signal CK_ready, and is used to generate mutually inverted data OUTP and OUTN. The delay circuit 721 provides the delayed clock signal Ring_DB.

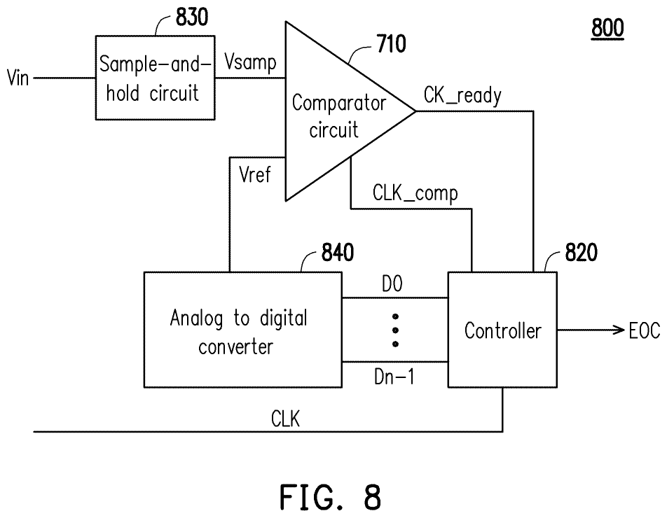

Please refer to FIG. 7 and FIG. 8 together. FIG. 8 shows a schematic diagram of an analog to digital converter 800 according to an embodiment of the disclosure. The analog to digital converter 800 includes a comparison circuit 810, a controller 820, a sample and hold circuit 830, and a digital to analog converter 840. In this embodiment, the controller 820 includes the 720. Moreover, the comparison circuit 810 operates in the same way as the comparison circuit 710, so details will not be repeated here. The sample and hold circuit 830 is coupled to the comparison circuit 810, and generates a sampling voltage Vsamp by performing a sample and hold operation on an input voltage Vin. The digital to analog converter 840 provides a reference voltage Vref. In detail, the controller 820 may execute a successive-approximation register (SAR) control mechanism, and provide digital signals D0 to Dn-1 to the digital to analog converter 840. The digital to analog converter 840 then generates the reference voltage Vref according to the digital signals D0 to Dn-1. When the digital to analog converter 840 completes the signal conversion, the controller 820 outputs an end of conversion signal EOC. When a metastable event occurs, the controller 820 may delay the clock signal CLK_comp.

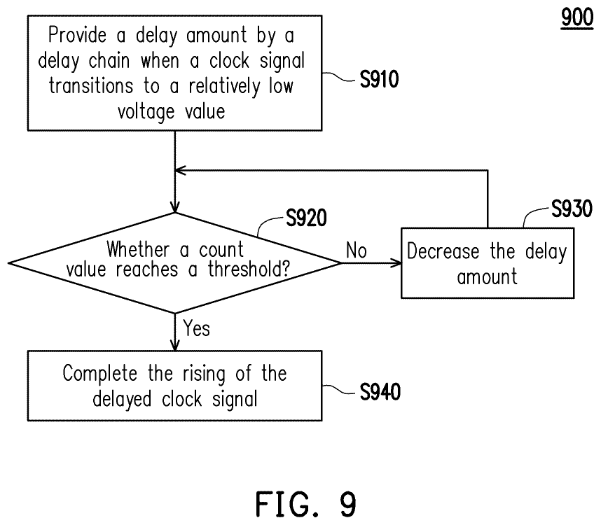

Please refer to FIG. 1, FIG. 5, and FIG. 9 together. FIG. 9 shows a delay amount controlling method 900 according to an embodiment of the disclosure. The clock signal CLK_bar received by the delay circuit 100 and the delay circuit 600 are the clock signal CK_Ring in FIG. 1 and the clock signal CLK in FIG. 6, respectively.

First, in Step S910, when the clock signal CLK_bar transitions to a relatively low voltage value, the delay chain 110 provides the delay amount. Then, in Step S920, the counter 510 counts the number of pulses of the delayed clock signal Ring_DB to generate the count value Con_V; and, the comparator 520 further compares the count value Con_V with the threshold Con_Vc to determine whether the count value Con_V reaches the threshold Con_Vc.

When it is determined that the count value Con_V does not reach the threshold Con_Vc, Step S930 is executed. In Step S930, the delay circuit 100 or 600 decreases the delay amount. Specifically, according to the embodiments in FIG. 2A, FIG. 3, and FIG. 4, the delay circuit 100 or 600 may adjust the delay amount by adjusting the sink current Isk and/or the source current Isr in the delay chain 110. After completing Step S930, Step S920 is executed again. Steps S920 and S930 are repeatedly executed until it is determined in Step S920 that the count value Con_V reaches the threshold Con_Vc.

When it is determined that the count value Con_V reaches the threshold Con_Vc, Step S940 is executed. In Step S940, the rising of the delayed clock signal Ring_DB is completed.

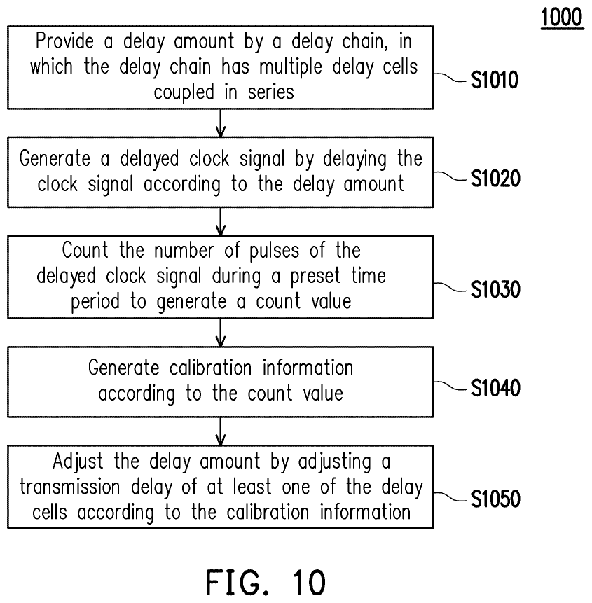

Please refer to FIG. 1 and FIG. 10 together. FIG. 10 shows a delay amount controlling method 1000 according to an embodiment of the disclosure. In Step S1010, the delay chain 110 provides a delay amount, in which the delay chain 110 has multiple delay cells coupled in series, for example, the delay cells D_CL[1] to D_CL[N] in FIG. 2. In Step S1020, the delay chain 110 generates the delayed clock signal Ring_DB by delaying the clock signal CK_Ring according to the delay amount. In Step S1030, the calibration circuit 120 counts the number of pulses of the delayed clock signal Ring_DB during the preset time period to generate the count value. In Step S1040, the calibration circuit 120 generates the calibration information Delay_C according to the count value. For example, when the count value is less than the threshold, the calibration information Delay_C is increased by an offset value. In Step S1050, the delay chain 110 adjusts the delay amount by adjusting the transmission delay of at least one of the delay cells according to the calibration information Delay_C. For example, when the calibration information Delay_C increases, the delay amount is decreased.

In summary, the delay circuit of the disclosure may adjust the delay amount of the delayed clock signal by limiting the number of pulses of the delayed clock signal and controlling the transmission delay of the selected delay cells. As a result, the variation range of the delay amount can be reduced to, for example, ±8%, and an appropriate delay amount can be generated to ensure that the system can operate correctly.

What is claimed is:

1. A delay circuit, comprising:
a delay chain comprising a plurality of delay cells coupled in series, wherein the delay chain provides a delay amount, and delays a clock signal by the delay amount to generate a delayed clock signal; and
a calibration circuit coupled to the delay chain, counting a number of pulses of the delayed clock signal during a preset time period to generate a count value, and generating calibration information according to the count value;
wherein the delay chain adjusts the delay amount by adjusting a transmission delay of at least one of the delay cells according to the calibration information.

2. The delay circuit as claimed in claim 1, wherein the calibration circuit comprises:
a counter counting the number of pulses of the delayed clock signal during a preset time period to generate a count value; and
a comparator coupled to the counter, comparing the count value with a threshold to generate the calibration information.

3. The delay circuit as claimed in claim 2, wherein in response to the count value being less than the threshold, the comparator increases the calibration information by an offset value.

4. The delay circuit as claimed in claim 3, wherein in response to the calibration information increasing, the delay amount of the delay chain decreases.

5. The delay circuit as claimed in claim 1, wherein the delay cells respectively comprise a plurality of signal buffers, and at least one of the delay cells is a selected delay cell,
wherein the selected delay cell adjusts the transmission delay according to the calibration information.

6. The delay circuit as claimed in claim 5, wherein the selected delay cell comprises:
a current source coupled in a path where a corresponding one of the signal buffers receives a reference ground voltage,
wherein the current source provides a sink current according to the calibration information.

7. The delay circuit as claimed in claim 5, wherein the selected delay cell comprises:
a current source coupled in a path where a corresponding one of the signal buffers receives a power supply voltage,
wherein the current source provides a source current according to the calibration information.

8. An analog to digital converter, comprising:
a comparison circuit comparing a sampling voltage with a reference voltage based on a clock signal to generate a comparison ready signal; and
a controller comprising a delay circuit and a logic circuit, wherein the logic circuit determines whether a metastable event occurs according to the comparison ready signal, and the delay circuit provides a delayed clock signal,
wherein the delay circuit comprises:
a delay chain comprising a plurality of delay cells coupled in series, wherein the delay chain provides a delay amount, and delays a clock signal by the delay amount to generate a delayed clock signal; and
a calibration circuit coupled to the delay chain, counting a number of pulses of the delayed clock signal during a preset time period to generate a count value, and generating calibration information according to the count value,
wherein the delay chain adjusts the delay amount by adjusting a transmission delay of at least one of the delay cells according to the calibration information.

9. The analog to digital converter as claimed in claim 8, wherein the calibration circuit comprises:
a counter counting the number of pulses of the delayed clock signal during a preset time period to generate a count value; and
a comparator coupled to the counter, comparing the count value with a threshold to generate the calibration information.

10. The analog to digital converter as claimed in claim 9, wherein in response to the count value being less than the threshold, the comparator increases the calibration information by an offset value.

11. The analog to digital converter as claimed in claim 8, wherein in response to the calibration information increasing, the delay amount of the delay chain decreases.

12. The analog to digital converter as claimed in claim 8, wherein the delay cells respectively comprise a plurality of signal buffers, and at least one of the delay cells is a selected delay cell,
wherein the selected delay cell adjusts the transmission delay according to the calibration information.

13. The analog to digital converter as claimed in claim 12, wherein the selected delay cell comprises:
a current source coupled in a path where a corresponding one of the signal buffers receives a reference ground voltage,
wherein the current source provides a sink current according to the calibration information.

14. The analog to digital converter as claimed in claim 12, wherein the selected delay cell comprises:
a current source coupled in a path where a corresponding one of the signal buffers receives a power supply voltage,
wherein the current source provides a source current according to the calibration information.

15. The analog to digital converter as claimed in claim 8, further comprising:
a sample and hold circuit coupled to the comparison circuit, and generating a sampling voltage by performing a sample and hold operation on an input voltage; and
a digital to analog converter providing the reference voltage.

16. A delay amount controlling method, comprising:
providing a delay amount by a delay chain, wherein the delay chain has a plurality of delay cells coupled in series;
generating a delayed clock signal by delaying a clock signal according to the delay amount;
counting a number of pulses of the delayed clock signal to generate a count value during a preset time period;
generating calibration information according to the count value; and
adjusting the delay amount by adjusting a transmission delay of at least one of the delay cells according to the calibration information.

17. The delay amount controlling method as claimed in claim 16, further comprising:
increasing the calibration information by an offset value in response to the count value being less than a threshold.

18. The delay amount controlling method as claimed in claim 16, further comprising:
decreasing the delay amount in response to the calibration information increasing.
